(19) United States
(12) Patent Application Publication
(10) Pub. No.: US 2007/0045612 A1
(43) Pub. Date: Mar. 1, 2007

(54) Organic thin film transistor and fabricating method thereof

(76) Inventors: Po-Yuan Lo, Hsinchu (TW); Zing-Way Pei, Hsinchu (TW)

Correspondence Address: HARNESS, DICKEY & PIERCE, P.L.C., P.O. BOX 8910, RESTON, VA, 20195, US

(21) Appl. No.: 11/439,345

(22) Filed: May 24, 2006

(30) Foreign Application Priority Data
Aug. 31, 2005 (TW) 094129949

(51) Int. Cl. H01L 29/08

(52) U.S. Cl. 257/40; 438/99

(57) ABSTRACT

An organic thin film transistor and a method for fabricating the same are provided. A multi-dielectric layer of the organic thin-film transistor is disposed on the substrate and the gate electrode, and then the organic layers-of the organic thin film transistor, the source and drain are produced. Because of the isolation effect of the multi-dielectric layer, the hydrophilic and lipophilic processes do not affect each other during the manufacturing of the organic thin film transistor. In addition, the multi-dielectric layer includes at least one organic dielectric layer and at least one liquid state deposited oxide silicon thin film.

### CROSS-REFERENCE TO RELATED APPLICATIONS

This non-provisional application claims priority under 35 U.S.C. §119(a) on Patent Application, No(s). 094129949 filed in Taiwan, R.O.C. on Aug. 31, 2005, the entire contents of which are hereby incorporated by reference.

### BACKGROUND OF THE INVENTION

1. Field of Invention

The invention relates to an organic thin film transistor and fabricating method thereof, and in particular to an organic thin film transistor with a multi-dielectric layer and fabricating method thereof.

2. Related Art

An organic thin film transistor (OTFT) is a transistor that is made by using an organic conjugated polymer or an oligomer as an active layer. When compared to the traditional silicon transistor, the OTFT can be made at a lower temperature. Therefore its substrate can use a lighter, thinner and cheaper plastic material, instead of a glass. On the other hand, the process for the OTFT is much easier, such as a printing process, which directly patterns an organic film. This is very helpful to reduce the amount of masks and vacuum evaporation equipments used. Further, because this process is suited for plastic substrate, it is more compatible to a roll-to-roll process, which has the benefit of cost reduction.

Presently, most OTFTs are made by a polymer thin film coating process or an ink jet printing process. Due to the advantages of a simple and low cost process, the OTFT can be competitively applied to a low end product or a disposable product. Additionally, it can also be applied to a radio frequency identification (RFID) product, a smart label or a smart tag. The present operation frequency of an OTFT is mostly based on the desire for an electronic paper to display a static image. If an OTFT is being used to display a motion picture, the operation frequency of the OTFT must be at least 1 KHz, or ten thousands to millions of Hz in order to give a higher resolution display image. Therefore, how to improve the process and the structure for the OTFT is a hot topic in the related industry.

Please refer to FIGS. 1 and 2. FIG. 1 is a cross section view of a conventional organic thin film transistor 11 with a bottom gate electrode. FIG. 2 is a cross section view of a conventional organic thin film transistor 12 with a top gate electrode. Among the processes and structures for the conventional organic thin film transistors11 and 12, the organic dielectric layers 41 disposed between a gate electrode 30 and an organic layer 50 are generally made with organic dielectric materials. However, organic dielectric materials are easily damaged by the, oxygen plasma used in the photo resist removal process. Besides, during the manufacturing process of OTFT, high polarity of organic solvent will damage the organic film of the OTFT, causing reduction of electron mobility and an increase of the threshold voltage. As a result, efficiency of the OTFT will be affected. In addition, the commonly used hydrophilic and lipophilic processes in the OTFT manufacturing process interfere to each other, which mean that defects may occur in the OTFT structure, causing the OTFT to be unstable or lack uniformity.

An object of the invention is to provide a multi-dielectric layer, comprising a liquid state deposited silicon oxide dielectric layer and an organic dielectric layer on a substrate and a gate electrode, followed by the processes for the organic layer, the source and drain electrodes of the OTFT to solve interference problems occurring with the commonly used hydrophilic and lipophilic processes in the OTFT manufacturing process.

Therefore, an embodiment of the method for fabricating an organic thin film transistor of the invention includes the steps of: providing a substrate; forming a gate electrode on the substrate; forming a multi-dielectric layer on the substrate and the gate electrode; forming an organic layer on the multi-dielectric layer; and forming a source electrode and a drain electrode on the multi-dielectric layer to electrically connect two ends of the organic layer.

The invention provides an embodiment of an organic thin film transistor structure, including: a substrate; a gate electrode formed on the substrate; a multi-dielectric layer formed on the gate electrode and the substrate; an organic layer formed on the multi-dielectric layer; a source formed on the multi-dielectric layer and electrically connected to one end of the organic layer; and a drain electrode formed on the multi-dielectric layer and electrically connected to the other end of the organic layer.

According to the invention, at least the following advantages can be achieved: the damage from an organic solvent to the dielectric layer can be reduced by the multi-dielectric layer, which comprises a liquid state deposited silicon oxide dielectric layer and an organic dielectric layer; the interference problem of the hydrophilic and lipophilic processes can be resolved by introducing the multi-dielectric layer; and the yield for the OTFT process, the stability and the uniformity of the device can also be improved.

### BRIEF DESCRIPTION OF THE DRAWINGS

The invention will become more fully understood from the detailed description given below, which is for illustration only and thus is not limitative of the invention, wherein:

FIG. 1 shows a cross section view of a conventional organic thin film transistor with a bottom gate electrode;

FIG. 2 shows a cross section view of a conventional organic thin film transistor with a top gate electrode;

FIG. 3 shows a cross section view of the first embodiment of an organic thin film transistor according to the invention;

FIG. 4 shows a cross section view of the second embodiment of an organic thin film transistor according to the invention;

FIG. 5 shows a flowchart of an embodiment for a process of an organic thin film transistor according to the invention; and

FIG. 6 shows a test result of an embodiment of an organic thin film transistor with a grown silicon oxide thin film according to the invention.

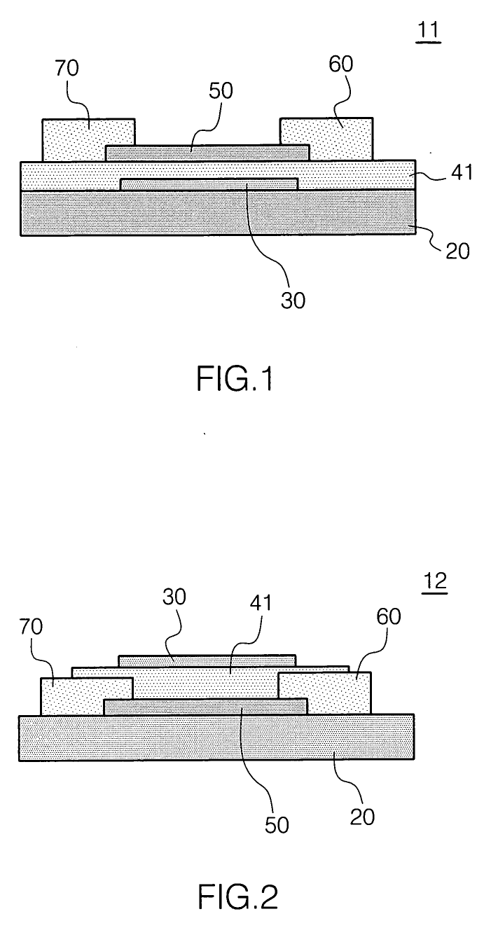

### DETAILED DESCRIPTION

One embodiment of the invention for the organic thin film transistor structures 13 and 14 and the fabricating methods thereof provides a multi-dielectric layer 40 on a substrate 20 and a gate electrode 30, and a further process for fabricating an organic layer 50, a source electrode 60 and a drain electrode 70 for the organic thin film transistors 13 and 14. Based on the isolation effect provided by the multi-dielectric layer 40, the hydrophilic process and a lipophilic process do not affect to each other during the fabricating process for the organic thin film transistors.

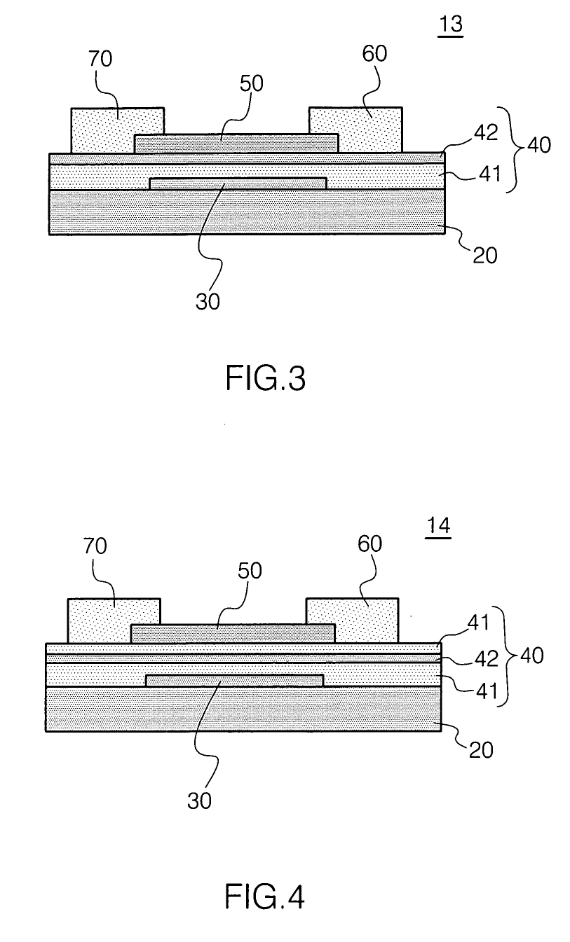

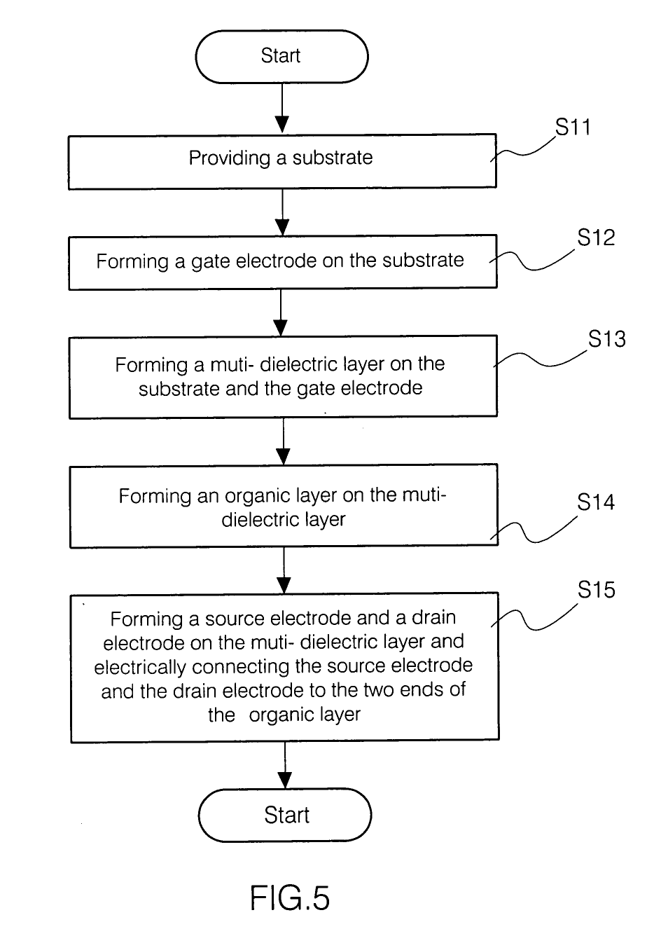

Please refer to FIGS. 3 and 4. FIG. 3 is a cross section view of the first embodiment of an organic thin film transistor according to the invention. FIG. 4 is a cross section view of the second embodiment of an organic thin film transistor according to the invention. The structure of the organic thin film transistors 13 and 14 include: a substrate 20; a gate electrode formed on the substrate 20; a multi-dielectric layer 40 formed on the gate electrode and the substrate 20; an organic layer 50 formed on the multi-dielectric layer 40; a source electrode 60 formed on the multi-dielectric layer 40 and electrically connected to one end of the organic layer 50; and a drain electrode 70 formed on the multi-dielectric layer 40 and electrically connected to the other end of the organic layer 50.

The substrate 20 is used for supporting structures, including the organic thin film transistors 13 and 14. The substrate 20 can be a plastic substrate 20 or an organic substrate 20.

The gate electrodes are first formed on the substrate 20 according to the invention.

The muti-dielectric layer 40 covers the gate and the substrate 20. The multi-dielectric layer 40 includes at least one organic dielectric layer 41 and at least one liquid phase oxide deposition dielectric layer 42. Referring to FIG. 3, a multi-dielectric layer 40 can include at least one organic dielectric layer 41 and at least one liquid phase oxide deposition dielectric layer 42 alternatively stacking together. Also, referring to FIG. 4, a multi-dielectric layer 40 can include one liquid phase oxide deposition dielectric layer 42 interposed between two organic dielectric layers 41.

The organic layer 50, also a semiconductor layer (active layer) for the organic thin film transistors 13 and 14, is formed on the multi-dielectric layer 40.

When the semiconductor layer is formed, a source electrode 60 and a drain electrode 70 are designed to connect the semiconductor layer to the exterior metal lines. Thus, they are formed on the multi-dielectric layer 40 to electrically connect to two ends of the semiconductor layer.

FIG. 5 is a flow chart for an embodiment of a fabricating method for the organic thin film transistors 13 and 14. The fabricating method includes: providing a substrate 20 (Step S11); forming a gate electrode 30 on the substrate 20 (Step S12); forming a multi-dielectric layer 40 on the substrate 20 and the gate electrode 30 (Step S13); forming an organic layer 50 on the multi-dielectric layer 40 (Step S14); and forming a source electrode 60 and a drain electrode 70 on the multi-dielectric layer 40 and electrically connecting the source electrode 60 and the drain electrode 70 to the two ends of the organic layer 50. (Step S15).

In Step S11, the substrate 20 can be a plastic substrate 20 or an organic substrate 20.

In Step S12, a gate electrode 30 is formed on the substrate 20.

In Step S13, a multi-dielectric layer 40 is formed on the substrate 20 and the gate electrode 30. The multi-dielectric layer 40 can include at least one organic dielectric layer 41 and at least one liquid phase oxide deposition dielectric layer 42. The organic dielectric layer 41 and the liquid phase oxide deposition dielectric layer can be alternatively stacked together, or if there are two organic dielectric layers then the liquid phase oxide deposition dielectric layer 42 can be interposed between the two organic dielectric layers 41.

In Step S14, an organic layer 50, also a semiconductor layer for the organic thin film transistor 13 or transistor 14, is formed on the multi-dielectric layer 40.

In Step S15, a source electrode 60 and a drain electrode 70 are formed on the multi-dielectric layer 40 and located on the two sides of the organic layer 50 to electrically connect to the two ends of the semiconductor layer respectively for further connecting exterior metal lines.

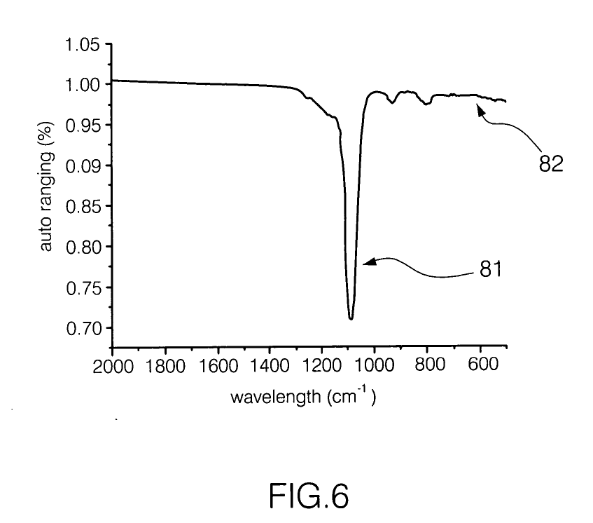

FIG. 6 shows a test result for an embodiment of an organic thin film transistor with a grown silicon oxide. It measured a bonding structure of a silicon oxide layer by Fourier Transform Infrared Spectroscopy (FTIR) equipment. In the figure, a stretching mode 81 and a bending mode 82 are also shown.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

What is claimed is:

1. A method for fabricating an organic thin film transistor, comprising:
providing a substrate;
forming a gate electrode on the substrate;
forming a multi-dielectric layer on the substrate and the gate electrode;
forming an organic layer on the multi-dielectric layer; and
forming a source electrode and a drain electrode on the multi-dielectric layer, wherein the source electrode and the drain electrode connect to two ends of the organic layer.

2. The method of claim 1 wherein the substrate is a plastic substrate or an organic substrate.

3. The method of claim 1 wherein the multi-dielectric layer comprises at least one organic dielectric layer and at least one liquid state deposited silicon oxide thin film.

4. The method of claim 1 wherein the multi-dielectric layer comprises at least one organic dielectric layer and at least one liquid state deposited silicon oxide thin film alternatively stacking together.

5. The method of claim 1 wherein the multi-dielectric layer comprises at least one liquid state deposited silicon oxide thin film interposing between two organic dielectric layers.

6. An organic thin film transistor, comprising:
a substrate;
a gate electrode formed on the substrate;
a multi-dielectric layer formed on the gate electrode and the substrate;
an organic layer formed on the multi-dielectric layer;
a source electrode formed on the multi-dielectric layer and connecting to one end of the organic layer; and
a drain electrode formed on the multi-dielectric layer and connecting to the other end of the organic layer.

7. The organic thin film transistor of claim 6 wherein the substrate is a plastic substrate or an organic substrate.

8. The organic thin film transistor of claim 6 wherein the multi-dielectric layer comprises at least one organic dielectric layer and at least one liquid state deposited silicon oxide thin film.

9. The organic thin film transistor of claim 6 wherein the multi-dielectric layer comprises at least one organic dielectric layer and at least one liquid state deposited silicon oxide thin film alternatively stacking together.

10. The organic thin film transistor of claim 6 wherein the multi-dielectric layer comprises at least one liquid state deposited silicon oxide thin film interposing between two organic dielectric layers.
